(19) United States
(12) Patent Application Publication
(10) Pub. No.: US 2025/0007476 A1
(43) Pub. Date: Jan. 2, 2025

(54) AUDIO AMPLIFIER CIRCUIT

(71) Applicant: ROHM CO., LTD., Kyoto-shi (JP)

(72) Inventor: Mitsuteru SAKAI, Kyoto-shi (JP)

(21) Appl. No.: 18/886,106

(22) Filed: Sep. 16, 2024

Related U.S. Application Data
(63) Continuation of application No. PCT/JP2023/008154, filed on Mar. 3, 2023.

(30) Foreign Application Priority Data
Mar. 17, 2022 (JP) 2022-043071

(51) Int. Cl. H03F 3/45

(52) U.S. Cl. CPC H03F 3/45475; H03F 2200/03; H03F 2200/351; H03F 2200/441

(57) ABSTRACT

A first voltage dividing circuit receives an internal power supply voltage at an input node. A buffer has an input node connected to an output node of the first voltage dividing circuit. A second voltage dividing circuit receives a power supply voltage V_{CC} at an input node. A voltage of the output node of the first voltage dividing circuit is a first reference voltage V_{FIL}, and a voltage of the output node of the second voltage dividing circuit is a second reference voltage V_{FILP}. A resistor Ro is connected between an output node of the buffer and the output node of the second voltage dividing circuit. The clamp circuit controls the voltage of the output node of the first voltage dividing circuit such that the second reference voltage does not exceed a limit voltage determined to be equal to or lower than the internal power supply voltage.

### CROSS REFERENCE TO RELATED APPLICATIONS

This application is a continuation under 35 U.S.C. § 120 of PCT/JP2023/008154, Mar. 3, 2023, which is incorporated herein by reference, and which claimed priority to Japanese Application No. 2022-043071, filed Mar. 17, 2022. The present application likewise claims priority under 35 U.S.C. § 119 to Japanese Application No. 2022-043071, filed Mar. 17, 2022, the entire content of which is also incorporated herein by reference.

### BACKGROUND

### 1. Technical Field

The present disclosure relates to an audio circuit.

### 2. Description of the Related Art

An in-vehicle audio system or a car navigation system includes an audio circuit. The audio circuit operates using a voltage from an in-vehicle battery as a power supply. Since the voltage of the battery greatly fluctuates from a rated voltage (for example, 14.4 V) during use, such a semiconductor integrated circuit is required to normally operate even under a severe fluctuation in the battery voltage, and the performance is tested in a load dump test, a cold crank test, or the like before the shipment. For example, in the load dump test, an overvoltage around 40 V is transiently applied to the power supply terminal of the semiconductor integrated circuit.

Some types of in-vehicle audio circuits are required to be capable of audio reproduction even when a 24 V battery is mistakenly connected.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram of an in-vehicle audio system including an audio amplifier circuit according to an embodiment,

FIG. 2 is a level diagram of the in-vehicle audio system of FIG. 1,

FIG. 3 is a circuit diagram of a bias circuit of FIG. 1,

FIG. 4 is a diagram for explaining an operation of the audio amplifier circuit of FIG. 1; and

FIG. 5 is a diagram for explaining an operation of the audio amplifier circuit of FIG. 1.

### DETAILED DESCRIPTION

### Outline of Embodiment

An outline of some exemplary embodiments of the present disclosure will be described. This outline describes some concepts of one or more embodiments in a simplified manner for the purpose of basic understanding of the embodiments as a preface to the detailed description to be given later and does not limit the breadth of the invention or disclosure. This outline is not a comprehensive overview of all possible embodiments and is not intended to identify key elements of all the embodiments or delineate the scope of some or all of the embodiments. For convenience, “one embodiment” may be used to refer to one embodiment (example or modification) or a plurality of embodiments (examples or modifications) disclosed herein.

An audio amplifier circuit according to one embodiment includes: an input gain circuit that amplifies an analog audio signal; a pulse modulator that includes an integrator and generates a pulse signal having a pulse width corresponding to an output signal of the input gain circuit; a power supply terminal that receives a power supply voltage; a driver that receives the power supply voltage and amplifies the pulse signal; a bias circuit that supplies a first reference voltage to the input gain circuit and supplies a second reference voltage to the integrator; and an internal voltage source that generates an internal power supply voltage. The bias circuit includes: a first voltage dividing circuit that receives the internal power supply voltage at an input node, a buffer having an input node connected to an output node of the first voltage dividing circuit, in which a signal of an output node is a first reference voltage; a second voltage dividing circuit that receives the power supply voltage at an input node, in which a signal of an output node is the second reference voltage; a resistor connected between the output node of the buffer and the output node of the second voltage dividing circuit; and a clamp circuit that controls the voltage of the output node of the first voltage dividing circuit such that the second reference voltage does not exceed a limit voltage determined to be equal to or less than the internal power supply voltage.

In a state where the power supply voltage is lower than a certain voltage level, the first reference voltage and the second reference voltage are proportional to the power supply voltage. When the power supply voltage exceeds the certain voltage level, the clamp circuit is activated, and the second reference voltage is clamped to a predetermined limit voltage. When the clamp circuit is active, the first reference voltage decreases as the power supply voltage increases. With this configuration, it is possible to increase the center level of the amplified audio signal in conformance with the power supply voltage while protecting the circuit from overvoltage, thus making it possible to continuously reproduce the audio signal.

In one embodiment, the clamp circuit may be a shunt regulator.

In one embodiment, the clamp circuit may include: a shunt transistor connected between the output node of the second voltage dividing circuit and a ground; and an error amplifier that receives a monitoring signal corresponding to the second reference voltage and a predetermined reference voltage, and has an output connected to a control terminal of the shunt transistor.

An audio amplifier circuit according to one embodiment includes: an input gain circuit that amplifies an analog audio signal; a pulse modulator that includes an integrator and generates a pulse signal having a pulse width corresponding to an output signal of the input gain circuit; a power supply terminal that receives a power supply voltage; a driver that receives the power supply voltage and amplifies the pulse signal; a bias circuit that supplies a first reference voltage to the input gain circuit and supplies a second reference voltage to the integrator; and an internal voltage source that generates an internal power supply voltage. The bias circuit includes: a first node that receives the internal power supply voltage; a second node that receives the power supply voltage; a third node at which the first reference voltage is generated; a fourth node at which the second reference voltage is generated; a fifth node to be connected to a capacitor; a first resistor connected between the first node and the fifth node; a second resistor connected between the fifth node and a ground; a buffer having an input node connected to the fifth node; a third resistor connected between the second node and the fourth node; a fourth resistor connected between the fourth node and a ground; a fifth resistor connected between an output node of the buffer and the fourth node; and a clamp circuit that receives a monitoring signal corresponding to the second reference voltage and sinks an electric current corresponding to an error between the second reference voltage and the monitoring signal from the third node.

In a state where the power supply voltage is lower than a certain voltage level, the first reference voltage and the second reference voltage are proportional to the power supply voltage. When the power supply voltage exceeds the certain voltage level, the clamp circuit is activated, and the first reference voltage is adjusted such that the second reference voltage maintains a predetermined target level. As a result, the audio signal can be continuously reproduced while protecting the circuit from overvoltage.

In one embodiment, the clamp circuit may include: a shunt transistor connected between the third node and a ground; and an error amplifier that receives a monitoring signal corresponding to the second reference voltage and a predetermined reference voltage, and has an output connected to a control terminal of the shunt transistor.

In one embodiment, the integrator may include: an operational amplifier that receives a second reference voltage at a non-inverting input terminal, a capacitor connected between an inverting input node and an output node of the operational amplifier, an input resistor connected between the inverting input node of the operational amplifier and an input node of the pulse modulator, and a feedback resistor connected between the inverting input node of the operational amplifier and an output node of the driver. When the resistance value of the input resistor is Ri and the resistance value of the feedback resistor is Rf, the resistance value of the fifth resistor may be Ri, and the resistance values of the third resistor and the fourth resistor may be 2×Rf.

In one embodiment, the audio amplifier circuit may be integrated on one semiconductor substrate. The term “integrated” includes a case where all components of a circuit are formed on a semiconductor substrate and a case where main components of the circuit are integrated, and some resistors, capacitors, and the like may be provided outside the semiconductor substrate to adjust a circuit constant. By integrating circuits on one chip, the circuit area can be reduced, while the characteristics of the circuit elements can be kept uniform.

### Embodiment

Hereinafter, a preferred embodiment will be described with reference to the drawings. The same or equivalent components, members, and processes illustrated in the drawings are denoted by the same reference numerals, and redundant description will be omitted as appropriate. In addition, the embodiments are not intended to limit the disclosure and the invention, but are merely examples, and all features described in the embodiments and combinations thereof are not necessarily essential to the disclosure and the invention.

“A state in which the member A is connected to the member B” herein includes not only a case where the member A and the member B are physically and directly connected to each other, but also a case where the member A and the member B are indirectly connected to each other via another member that does not substantially affect electrical connection between the member A and the member B or that does not impair a function or an effect produced by coupling between the member A and the member B.

Similarly, “a state in which the member C is connected (provided) between the member A and the member B” includes not only a case where the member A and the member C or the member B and the member C are directly connected to each other, but also a case where the member C is indirectly between the member A and the member B via another member that does not substantially affect electrical connection between the member A and the member B or that does not impair a function or an effect produced by coupling between the member A and the member B.

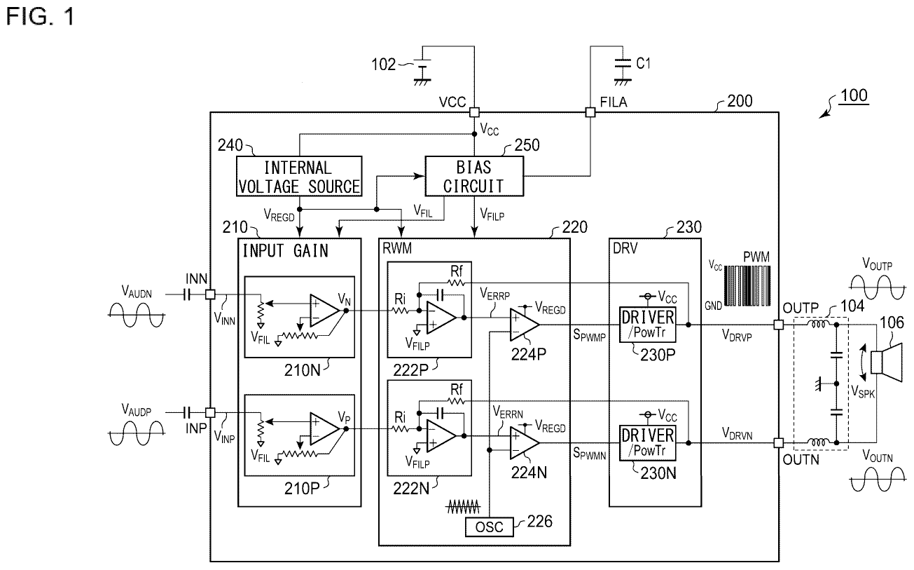

FIG. 1 is a circuit diagram of an in-vehicle audio system 100 including an audio amplifier circuit 200 according to an embodiment. The in-vehicle audio system 100 includes an in-vehicle battery (hereinafter, simply referred to as a battery) 102, a filter 104, a speaker 106, and an audio amplifier circuit 200.

The battery 102 generates a battery voltage V_{BAT} with a rating of 12 V. The audio amplifier circuit 200 is a functional integrated circuit (IC) in which circuits are integrated on one semiconductor substrate, and the battery voltage V_{BAT} is supplied to the audio amplifier circuit 200 as a power supply voltage V_{CC}. The audio amplifier circuit 200 receives an input audio signal V_{IN} from a sound source (not illustrated), amplifies the input audio signal V_{IN}, and drives the speaker 106 that is a load. In the present embodiment, the in-vehicle audio system 100 is configured with a fully differential amplifier, and the input audio signal V_{AUD} is a differential signal including V_{AUDN} and V_{AUDP} of opposite phases.

The audio amplifier circuit 200 receives the differential signals V_{AUDN} and V_{AUDP} at differential input terminals INN and INP from the sound source (not illustrated) via a coupling capacitor. In addition, the speaker 106 is connected to differential output terminals OUTP and OUTN of the audio amplifier circuit 200 via a filter 104. A suffix P attached to signals or terminals represents a positive phase, and a suffix N represents a negative phase. When both components of the positive phase and the negative phase are collectively mentioned, the suffix is omitted.

The audio amplifier circuit 200 is a class D amplifier (switching amplifier) and generates a pulse drive signal having a duty cycle corresponding to the input audio signal V_{IN}. A high frequency component of the pulse drive signal VDRV is removed by the filter 104, and an analog audio signal V_{OUT} in the audio band is supplied to the speaker 106.

A power supply terminal VCC of the audio amplifier circuit 200 is connected to the battery 102 and receives the power supply voltage V_{CC}. An external capacitor C1 is connected to a capacitor connection terminal FILA. Pulse drive signals V_{DRVP} and V_{DRVN} have an amplitude equal to that of the power supply voltage V_{CC}.

The audio amplifier circuit 200 includes an input gain circuit 210, a pulse width modulation (PWM) circuit 220, a driver circuit 230, an internal voltage source 240, and a bias circuit 250. Each of the input gain circuit 210, the PWM circuit 220, and the driver circuit 230 has the same configuration for both the positive-phase signal and the negative-phase signal.

The internal voltage source 240 generates an internal power supply voltage V_{REGD}.

The input gain circuit 210 operates using the internal power supply voltage V_{REGD} supplied from the internal voltage source 240 as a power supply voltage. In addition, the input gain circuit 210 is supplied with a first reference voltage V_{FIL} from the bias circuit 250. The first reference voltage V_{FIL} is equal to or larger than the maximum amplitude of V_{AUD}. In the present embodiment, the first reference voltage V_{FIL} is a voltage ½ times the internal power supply voltage V_{REGD}.

$${V}_{FIL} = {V}_{REGD} / 2 \qquad ( 1 )$$

The internal power supply voltage V_{REGD} can be, for example, 5.3 V, and the first reference voltage V_{FIL} can be 2.65 V.

The input gain circuit 210 amplifies the input audio signal V_{AUD}. Specifically, an input gain circuit 210N amplifies the negative-phase audio signal V_{AUDN}, and an input gain circuit 210P amplifies the positive-phase audio signal V_{AUDP}. Gains of the input gain circuits 210N and 210P are g₁.

The differential audio signal V_{AUDN} is input to the input terminal INN via the coupling capacitor. A signal V_{INN} of the input terminal INN is:

$${V}_{INN} = {V}_{AUDN} + {V}_{FIL} \qquad ( 2 )$$

and An output signal of the input gain circuit 210N is:

$${V}_{N} = {g}_{1} \times {V}_{AUDN} + {V}_{FIL} \qquad ( 3 )$$

Similarly, a signal V_{INP} of the input terminal INP is:

$${V}_{INP} = {V}_{AUDP} + {V}_{FIL} \qquad ( 4 )$$

An output signal of the input gain circuit 210P is:

$${V}_{P} = {g}_{1} \times {V}_{AUDP} + {V}_{FIL} \qquad ( 5 )$$

The PWM circuit 220 is a feedback type pulse modulator. The PWM circuit 220 includes integrators 222P and 222N, comparators 224P and 224N, and an oscillator 226. The PWM circuit 220 is supplied with a second reference voltage V_{FILP} from the bias circuit 250.

The integrator 222P receives the output signal V_{N} of the input gain circuit 210N in the preceding stage and the drive pulse V_{DRVP} generated by a driver circuit 230P in the subsequent stage. The second reference voltage V_{FILP} is input to a non-inverting input node of the integrator 222P. The integrator 222P functions as an error amplifier and amplifies an error between an integrated value (smoothed voltage) of a voltage obtained by internally dividing the two voltages V_{N} and V_{DRVP} by the resistors Ri and Rf and the second reference voltage V_{FILP}.

The comparator 224P compares an output voltage V_{ERRP} of the integrator 222P with a periodic signal of a triangular wave generated by the oscillator 226 and generates a pulse signal S_{PWMP}. The power supply voltage of the comparator 224P is the internal power supply voltage V_{REGD}, the high level of the pulse signal S_{PWMP} is V_{REGD}, and the low level of the pulse signal S_{PWMP} is 0 V.

The driver circuit 230 includes a driver circuit 230P and a driver circuit 230N. The driver circuit 230P is supplied with the power supply voltage V_{CC}. The driver circuit 230P receives the pulse signal S_{PWMP} and generates the drive pulse V_{DRVP} whose high level is the power supply voltage V_{CC} and low level is GND (0 V). A carrier wave component of the drive pulse V_{DRVP} is removed by the external filter 104, and the output voltage V_{OUTP} is generated.

The integrator 222P, the comparator 224P, and the driver circuit 230P form a feedback loop. This feedback loop causes the DC (direct current) component of the output voltage V_{OUTP} (and V_{DRVP}) to become V_{FILP}, and the AC (alternating current) component (audio component) to become g₁×(−g₂)×V_{AUDN}. g₂ is a gain of the PWM circuit 220 and defined as g₂=Rf/Ri.

The integrator 222N and the comparator 224N also operate as described above. The DC component of the output voltage V_{OUTN} (and V_{DRVN}) becomes V_{FILP}, and the AC component (audio component) becomes g₁×(−g₂)×V_{INP}.

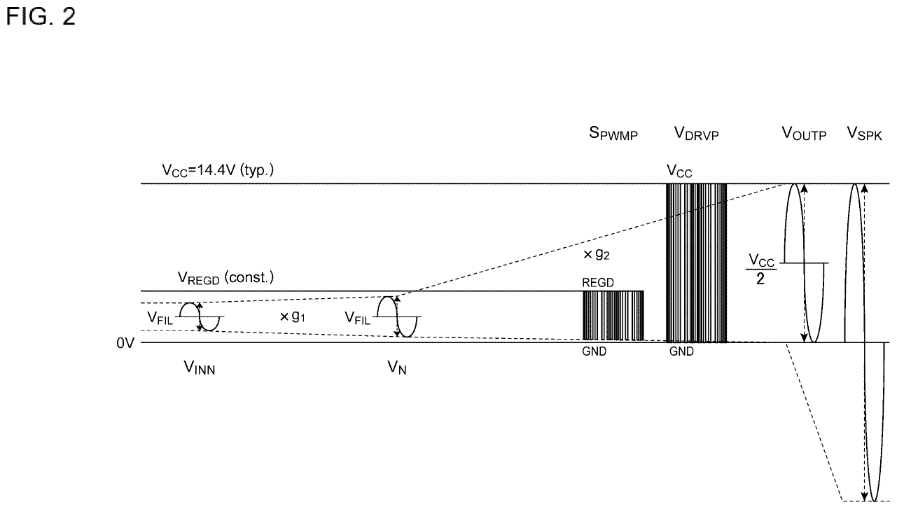

The entire configuration of the in-vehicle audio system 100 has been described above. FIG. 2 is a level diagram of the in-vehicle audio system 100 of FIG. 1. FIG. 2 illustrates the voltage V_{INN} of the differential input terminal INN, the output signal V_{N} of the input gain circuit 210N, the PWM signal S_{PWMP}, the drive signal V_{DRVP}, and the output voltage V_{OUTP}.

The first reference voltage V_{FIL} is ½ of the internal power supply voltage V_{REGD}, and the voltage V_{INN} is a signal obtained by superimposing the audio signal V_{AUDN} on the bias level V_{FIL}.

The bias level of the output signal V_{N} of the input gain circuit 210N is V_{FIL}, and the signal amplitude (AC component) is g₁ times the input signal V_{AUDN}.

The PWM signal S_{PWMP} is a pulse signal whose high level is the internal power supply voltage V_{REGD} and low level is the ground voltage GND (0 V), and whose duty cycle corresponds to the voltage V_{N}. Specifically, when V_{N}=V_{FIL}, the duty cycle of the PWM signal S_{PWMP} is 50%. Since the integrator 222P is an inverting amplifier, the duty cycle of the PWM signal S_{PWMP} is higher than 50% when V_{N} is lower than V_{FIL}, and the duty cycle is lower than 50% when V_{N} is higher than V_{FIL}.

The drive signal V_{DRVP} is a pulse signal whose high level is the power supply voltage V_{CC} and low level is the ground voltage GND (0 V). The duty cycle of the drive signal V_{DRVP} is equal to the duty cycle of the PWM signal S_{PWMP}.

The bias level of the output signal V_{OUTP} is V_{CC}/2, and the signal amplitude (AC component) is g₁×(−g₂) times the input signal V_{AUDN}.

A voltage V_{SPK} applied across the speaker 106 is V_{OUTP}−V_{OUTN}, and the signal amplitude is twice the output signal V_{OUTP}.

Next, a configuration of the bias circuit 250 will be described.

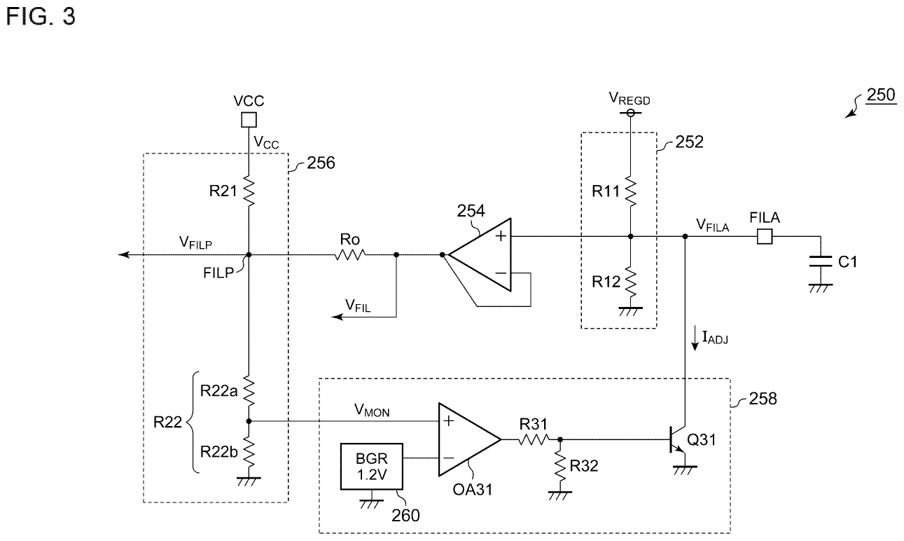

FIG. 3 is a circuit diagram of the bias circuit 250 of FIG. 1. The bias circuit 250 includes a first voltage dividing circuit 252, a buffer 254, a second voltage dividing circuit 256, a clamp circuit 258, and a resistor Ro.

The first voltage dividing circuit 252 receives the internal power supply voltage V_{REGD} at an input node. The first voltage dividing circuit 252 includes resistors R11 and R12. The resistor R11 is connected between the input node of the first voltage dividing circuit 252 and the capacitor connection terminal FILA, and the resistor R12 is connected between the capacitor connection terminal FILA and a ground.

When the resistance values of the resistors R11 and R12 of the first voltage dividing circuit 252 are determined to be equal to each other (R11=R12), a voltage V_{FILA} of the capacitor connection terminal FILA is:

$${V}_{FILA} = {V}_{REGD} / 2 \qquad ( 6 )$$

The buffer 254 has an input node connected to an output node of the first voltage dividing circuit 252, that is, the capacitor connection terminal FILA. A signal of an output node of the buffer 254 is the first reference voltage V_{FIL}, which is equal to the voltage V_{FILA} of the capacitor connection terminal FILA. Therefore, the first reference voltage V_{FIL} in the normal state (non-overvoltage state) is:

$${V}_{FIL} = {V}_{FILA} = {V}_{REGD} / 2 \qquad ( 7 )$$

The second voltage dividing circuit 256 receives the power supply voltage V_{CC} at an input node. A voltage generated at an output node FILP of the second voltage dividing circuit 256 is the second reference voltage V_{FILP}. The second voltage dividing circuit 256 includes resistors R21 and R22. The resistor R21 is connected between the input node and the output node of the second voltage dividing circuit 256, and the resistor R22 is connected between the output node of the second voltage dividing circuit 256 and a ground.

The resistor Ro is connected between the output node of the buffer 254 and the output node of the second voltage dividing circuit 256. The ratio of the resistance values between the resistors Ro, R21, and R22 can be Ri:2Rf:2Rf. The resistance values may be such that Ro=Ri and R21=R22=2×Rf. From g₂=Rf/Ri as described above, the ratio can be:

Ro:R21:R22=1:2g₂:2g₂

At this time, the second reference voltage V_{FILP} is expressed by the following Formula (8) in the normal state.

$$[ Formula 1 ]$$

$${V}_{FILP} = \frac{{V}_{CC}}{2} + ( \frac{{V}_{CC}}{2} - \frac{{V}_{FIL}}{2} ) \cdot \frac{Ri}{Ri + Rf} \qquad ( 8 )$$

The clamp circuit 258 controls the voltage of the output node of the first voltage dividing circuit 252 such that the second reference voltage V_{FILP} does not exceed a limit voltage V_{LIM} determined to be equal to or lower than the internal power supply voltage V_{REGD}. For example, when V_{REGD}=5.3 V, the limit voltage V_{LIM} can be 5 V. That is, the clamp circuit 258 is inactive when V_{CC}<2×V_{LIM}, and is activated when V_{CC}>2×V_{LIM}.

The resistor R22 includes resistors R22a and R22b connected in series. A voltage V_{MON} obtained by dividing the second reference voltage V_{FILP} is generated at a connection node between the resistors R22a and R22b. The clamp circuit 258 monitors the divided voltage (referred to as a monitoring voltage) V_{MON} and sinks a sink current I_{ADJ} from the capacitor connection terminal FILA such that the monitoring voltage V_{MON} does not exceed a reference voltage V_{BGR}.

The clamp circuit 258 is a shunt regulator, and includes a bandgap reference circuit 260, an operational amplifier OA31, resistors R31 and R32, and a shunt transistor Q31.

The bandgap reference circuit 260 generates the reference voltage V_{BGR} of 1.2 V. The shunt transistor Q31 is connected to the output node of the second voltage dividing circuit 256, that is, between the capacitor connection terminal FILA and a ground. The operational amplifier OA31 is an error amplifier and receives the monitoring signal V_{MON} corresponding to the second reference voltage V_{FILP} and the reference voltage V_{BGR}. An output of the operational amplifier OA31 is divided by the resistors R31 and R32 and supplied to a control terminal (base) of the shunt transistor Q31.

In the state of V_{CC}>2×V_{LIM}, that is, in the state of V_{MON}>V_{BGR}, the current amount of the sink current I_{ADJ} is adjusted by the clamp circuit 258 through a feedback, the voltage of the capacitor connection terminal FILA drops, and as a result, the monitoring voltage V_{MON} becomes equal to the reference voltage V_{BGR}.

In the state of V_{CC}<2×V_{LIM}, that is, in the state of V_{MON}<V_{BGR}, the shunt transistor Q31 is turned off and the sink current I_{ADJ} is 0, and as a result, the voltage of the capacitor connection terminal FILA is not affected. At this time, the second reference voltage V_{FILP} is expressed by the following Formula (8).

The configuration of the bias circuit 250 has been described above. Next, an operation of the in-vehicle audio system 100 of FIG. 1 will be described.

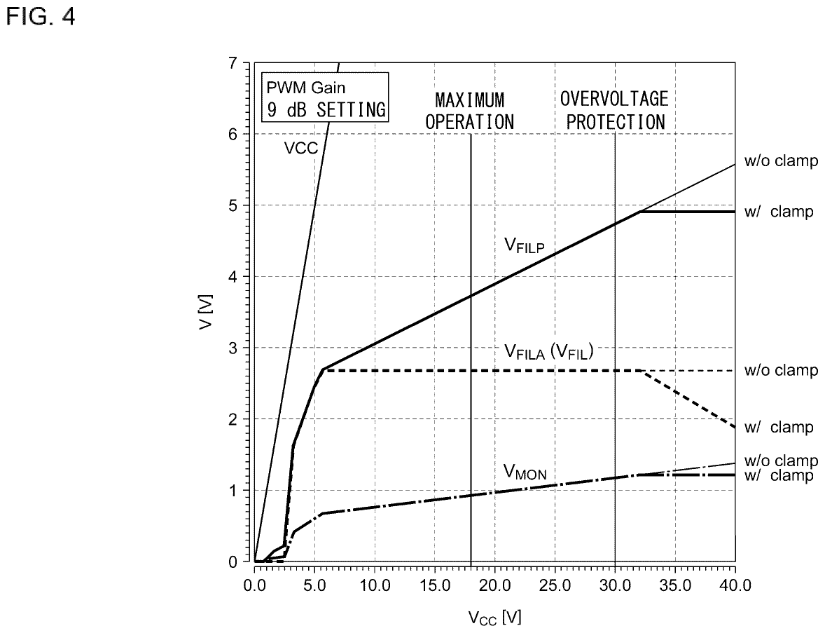

FIG. 4 is a diagram for explaining an operation of the audio amplifier circuit 200 of FIG. 1. The horizontal axis represents the power supply voltage V_{CC}, and the vertical axis represents various voltages. The gain g₂ of the PWM circuit 220 is 9 dB.

Specifically, the voltage V_{FILA} (first reference voltage V_{FIL}) of the capacitor connection terminal FILA, the second reference voltage V_{FILP}, and the monitoring voltage V_{MON} are illustrated. For comparison, various voltages when the clamp circuit 258 is operated (w/clamp) are indicated by solid lines, and various voltages when the clamp circuit 258 is not operated (w/o clamp) are indicated by broken lines.

The battery voltage V_{BAT} may be approximately 9 to 14.4 V for a 12 V battery and 18 to 30 V for a 24 V battery. The audio amplifier circuit 200 is designed assuming the 12 V battery 102, and is designed with a maximum operating voltage of 18 V considering a margin from 14.4 V. In addition, even in a case where the 24 V battery is mistakenly connected, the audio amplifier circuit 200 is required to maintain audio reproduction of 1 W, and therefore, the audio amplifier circuit 200 is designed to have an overvoltage protection voltage of V_{CC}=30 V.

In a case where the clamp circuit 258 is not operated, when the power supply voltage V_{CC} becomes an overvoltage, the voltage V_{FILP} increases linearly with respect to the power supply voltage V_{CC}. On the other hand, the clamp circuit 258 can be operated to, even if the power supply voltage V_{CC} becomes an overvoltage, maintain the voltage V_{FILP} at a voltage level allowing the audio signal to be amplified without being clipped.

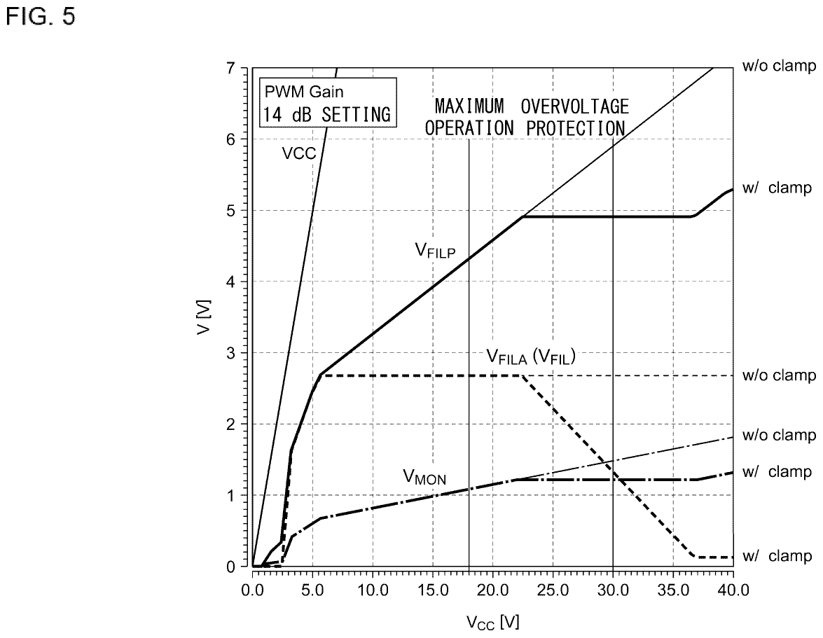

FIG. 5 is a diagram for explaining an operation of the audio amplifier circuit 200 of FIG. 1. In FIG. 5, the gain g₂ of the PWM circuit 220 is 14 dB.

The operation of the audio amplifier circuit 200 has been described above.

The audio amplifier circuit 200 operates such that the second reference voltage V_{FILP} does not exceed a limit voltage V_{LIM} determined to be equal to or lower than the internal power supply voltage V_{REGD}. This makes it possible to enhance resistance to an overvoltage while suppressing an increase in the circuit area due to the adoption of a high withstand voltage element such as a double-diffused MOS (DMOS).

The advantage of the audio amplifier circuit 200 is made clear by a comparison with the comparative technique. In the comparative technique, when the power supply voltage V_{CC} becomes an overvoltage, only the second reference voltage V_{FILP} is clamped without reducing the first reference voltage V_{FIL} (V_{FILA}). In this case, the bias voltage (midpoint voltage) of the drive voltage V_{DRVP} (V_{DRVN}) deviates from V_{CC}/2.

On the other hand, in the audio amplifier circuit 200 according to the embodiment, when the power supply voltage V_{CC} becomes an overvoltage, the first reference voltage V_{FIL} (V_{FILA}) drops as the power supply voltage V_{CC} increases. As a result, the bias voltage (midpoint voltage) of the drive voltage V_{DRVP} (V_{DRVN}) can be maintained at V_{CC}/2.

According to the present embodiment, even in a case where the optimum gain is set in the operation guarantee power supply voltage range, an output equivalent to 1 W is possible when the 24 V battery is mistakenly connected. Conversely, since it is not necessary to set the gain g₂ of the PWM circuit 220 high on the assumption of overvoltage operation, it is possible to realize operation in an overvoltage state without deteriorating characteristics of noise and offset voltage.

### Supplement

The techniques disclosed herein are as follows:

### Item 1

An audio amplifier circuit
including:
an input gain circuit that amplifies an analog audio signal,
a pulse modulator that includes an integrator and generates a pulse signal having a pulse width corresponding to an output signal of the input gain circuit,
a power supply terminal that receives a power supply voltage,
a driver that receives the power supply voltage and amplifies the pulse signal,
a bias circuit that supplies a first reference voltage to the input gain circuit and supplies a second reference voltage to the integrator; and
an internal voltage source that generates an internal power supply voltage,
wherein
the bias circuit includes:
a first voltage dividing circuit that receives the internal power supply voltage at an input node;
a buffer having an input node connected to an output node of the first voltage dividing circuit, a signal of an output node being the first reference voltage,
a second voltage dividing circuit that receives the power supply voltage at an input node, a signal of an output node being the second reference voltage,
a resistor connected between the output node of the buffer and the output node of the second voltage dividing circuit; and
a clamp circuit that controls a voltage of the output node of the first voltage dividing circuit such that the second reference voltage does not exceed a limit voltage determined to be equal to or lower than the internal power supply voltage.

### Item 2

The audio amplifier circuit according to item 1, wherein the clamp circuit is a shunt regulator.

### Item 3

The audio amplifier circuit according to item 1 or 2, wherein
the clamp circuit may include:
a shunt transistor connected between the output node of the second voltage dividing circuit and a ground; and
an error amplifier that receives a monitoring signal corresponding to the second reference voltage and a predetermined reference voltage, and has an output connected to a control terminal of the shunt transistor.

### Item 4

An audio amplifier circuit
including:
an input gain circuit that amplifies an analog audio signal,
a pulse modulator that includes an integrator and generates a pulse signal having a pulse width corresponding to an output signal of the input gain circuit,
a power supply terminal that receives a power supply voltage,
a driver that receives the power supply voltage and amplifies the pulse signal,
a bias circuit that supplies a first reference voltage to the input gain circuit and supplies a second reference voltage to the integrator; and
an internal voltage source that generates an internal power supply voltage,
wherein
the bias circuit includes:
a first node that receives the internal power supply voltage,
a second node that receives the power supply voltage,
a third node at which the first reference voltage is generated,
a fourth node at which the second reference voltage is generated,
a fifth node to which a capacitor is to be connected,
a first resistor connected between the first node and the fifth node,
a second resistor connected between the fifth node and a ground,
a buffer having an input node connected to the fifth node,
a third resistor connected between the second node and the fourth node,
a fourth resistor connected between the fourth node and the ground,
a fifth resistor connected between an output node of the buffer and the fourth node, and
a clamp circuit that receives a monitoring signal corresponding to the second reference voltage and sinks a current corresponding to an error between a predetermined reference voltage and the monitoring signal from the third node.

### Item 5

The audio amplifier circuit according to item 4, wherein
the clamp circuit includes:
a shunt transistor connected between the third node and a ground; and
an error amplifier that receives the monitoring signal and the predetermined reference voltage, and has an output connected to a control terminal of the shunt transistor.

### Item 6

The audio amplifier circuit according to item 4 or 5, wherein
the integrator includes:
an operational amplifier that receives the second reference voltage at a non-inverting input terminal;
a capacitor connected between an inverting input node and an output node of the operational amplifier;
an input resistor connected between the inverting input node of the operational amplifier and an input node of the pulse modulator; and
a feedback resistor connected between the inverting input node of the operational amplifier and an output node of the driver,
wherein, when a resistance value of the input resistor is Ri and a resistance value of the feedback resistor is Rf, a resistance value of the fifth resistor is Ri, and resistance values of the third resistor and the fourth resistor are 2×Rf.

### Item 7

The audio amplifier circuit according to any one of items 1 to 6, wherein the audio amplifier circuit is integrated on one semiconductor substrate.

### Item 8

An in-vehicle electronic apparatus including the audio amplifier circuit according to any one of items 1 to 7.

What is claimed is:

1. An audio amplifier circuit comprising:
an input gain circuit structured to amplify an analog audio signal,
a pulse modulator including an integrator and structured to generate a pulse signal having a pulse width corresponding to an output signal of the input gain circuit,
a power supply terminal structured to receive a power supply voltage,
a driver structured to receive the power supply voltage and amplify the pulse signal,
a bias circuit structured to supply a first reference voltage to the input gain circuit and supply a second reference voltage to the integrator; and
an internal voltage source structured to generate an internal power supply voltage,
wherein
the bias circuit includes:
a first voltage dividing circuit structured to receive the internal power supply voltage at an input node;
a buffer having an input node connected to an output node of the first voltage dividing circuit, a signal of an output node being the first reference voltage,
a second voltage dividing circuit structured to receive the power supply voltage at an input node, a signal of an output node being the second reference voltage,
a resistor connected between the output node of the buffer and the output node of the second voltage dividing circuit; and
a clamp circuit structured to control a voltage of the output node of the first voltage dividing circuit such that the second reference voltage does not exceed a limit voltage determined to be equal to or lower than the internal power supply voltage.

2. The audio amplifier circuit according to claim 1, wherein the clamp circuit is a shunt regulator.

3. The audio amplifier circuit according to claim 1, wherein
the clamp circuit includes:
a shunt transistor connected between the output node of the second voltage dividing circuit and a ground; and
an error amplifier structured to receive a monitoring signal corresponding to the second reference voltage and a predetermined reference voltage, and have an output connected to a control terminal of the shunt transistor.

4. An audio amplifier circuit
comprising:
an input gain circuit structured to amplify an analog audio signal,
a pulse modulator including an integrator and structured to generate a pulse signal having a pulse width corresponding to an output signal of the input gain circuit,
a power supply terminal structured to receive a power supply voltage,
a driver structured to receive the power supply voltage and amplify the pulse signal,
a bias circuit structured to supply a first reference voltage to the input gain circuit and supply a second reference voltage to the integrator; and
an internal voltage source structured to generate an internal power supply voltage,
wherein
the bias circuit includes:
a first node structured to receive the internal power supply voltage,
a second node structured to receive the power supply voltage,
a third node at which the first reference voltage is generated,
a fourth node at which the second reference voltage is generated,
a fifth node to which a capacitor is to be connected,
a first resistor connected between the first node and the fifth node,
a second resistor connected between the fifth node and a ground,
a buffer having an input node connected to the fifth node,
a third resistor connected between the second node and the fourth node,
a fourth resistor connected between the fourth node and the ground,
a fifth resistor connected between an output node of the buffer and the fourth node; and
a clamp circuit structured to receive a monitoring signal corresponding to the second reference voltage and sink a current corresponding to an error between a predetermined reference voltage and the monitoring signal from the third node.

5. The audio amplifier circuit according to claim 4, wherein
the clamp circuit includes:
a shunt transistor connected between the third node and a ground; and
an error amplifier structured to receive the monitoring signal and the predetermined reference voltage, and have an output connected to a control terminal of the shunt transistor.

6. The audio amplifier circuit according to claim 4, wherein
the integrator includes:
an operational amplifier structured to receive the second reference voltage at a non-inverting input terminal,
a capacitor connected between an inverting input node and an output node of the operational amplifier,
an input resistor connected between the inverting input node of the operational amplifier and an input node of the pulse modulator; and
a feedback resistor connected between the inverting input node of the operational amplifier and an output node of the driver,
wherein, when a resistance value of the input resistor is Ri and a resistance value of the feedback resistor is Rf, a resistance value of the fifth resistor is Ri, and resistance values of the third resistor and the fourth resistor are 2×Rf.

7. The audio amplifier circuit according to claim 1, wherein the audio amplifier circuit is integrated on one semiconductor substrate.

8. An in-vehicle electronic apparatus comprising the audio amplifier circuit according to claim 1.
